(19) United States
(12) Patent Application Publication
(10) Pub. No.: US 2011/0025378 A1
(43) Pub. Date: Feb. 3, 2011

(54) SEMICONDUCTOR INTEGRATED CIRCUIT AND LAYOUT METHOD THEREOF

(75) Inventor: Yukio KOZAWA, Kanagawa (JP)

Correspondence Address: FOLEY AND LARDNER LLP;SUITE 500, 3000 K STREET NW, WASHINGTON, DC, 20007, US

(73) Assignee: Renesas Electronics Corporation

(21) Appl. No.: 12/841,428

(22) Filed: Jul. 22, 2010

(30) Foreign Application Priority Data
Aug. 3, 2009 (JP) 2009-181010

(51) Int. Cl. H03K 19/00; G06F 17/50

(52) U.S. Cl. 326/101; 716/119

(57) ABSTRACT

A layout method for a semiconductor integrated circuit includes, generating logic cell layout data by arranging logic cells and signal lines connected to said logic cells, by using an automatic place and root tool, generating variable capacitor cell layout data by arranging variable capacitor cells and control lines for controlling capacitance value of the variable capacitor cells, by using the automatic place and root tool, and generating layout data of the semiconductor integrated circuit, based on the logic cell layout data and the variable capacitor cell layout data. The generating variable capacitor cell layout data includes, arranging the control lines so as to be same as said signal lines in a resistance of a unit length in one wiring layer.

### INCORPORATION BY REFERENCE

This patent application claims a priority on convention based on Japanese Patent Application No. 2009-181010. The disclosure thereof is incorporated herein by reference.

### BACKGROUND OF THE INVENTION

1. Field of the Invention

The present invention relates to a semiconductor integrated circuit, a layout method for the semiconductor integrated circuit, a layout program for the semiconductor integrated circuit and a layout device for the semiconductor integrated circuit.

2. Description of Related Art

In recent years, importance of protection against a radio wave environment has been increased. In order to suppress an EMI (Electromagnetic interference) noise, a capacitor has been installed in a semiconductor integrated circuit itself mounted on an electric device.

When designing the semiconductor integrated circuit that has the capacitor as a countermeasure for EMI, logic cells indicating logic elements are firstly arranged by using an automatic place and rout tool. Next, numerous capacitor cells indicating capacitors are arranged in a region other than the logic cells.

Generally, when an entire capacitance value C of the numerous capacitor cells is large, an excellent countermeasure for EMI can be obtained. However, a resonance frequency f (=1/2π√LC) may be generated by the capacitance value C and inductance L formed by a package or the like. If the resonance frequency F overlaps with n (n is an integer number) times of an operation frequency, the EMI is amplified by the resonance.

If the operation frequency is constant, the capacitance value C can be decided such that the resonance is prevented. However, if an ASIC (Application Specific Integrated Circuit) or the like is used as the semiconductor integrated circuit, there is a case that a user changes the operation frequency after designing or manufacturing. The user must set an operation condition (a frequency) such that the resonance is prevented.

For this reason, it is considered to use a variable capacitor cell.

As a related technology, a variable capacitance circuit of a MOS type is cited in document 1 (Japanese patent publication Showa-62-156853). This MOS type variable capacitance circuit includes a semiconductor substrate, a MOS type transistor formed on the semiconductor substrate, a means for applying a back gate voltage to the semiconductor substrate, a control means for connecting a source and drain of the MOS type transistor and applying a control voltage to the connection point. In the variable capacitance circuit of the MOS type, the control voltage is variable, and capacitance between a gate and a source or drain can be variable.

As another related technology, a semiconductor integrated circuit described in document 2 (Japanese patent publication 2007-250604A) is cited. This semiconductor integrated circuit includes a condenser group having a plurality of condenser, a switching circuit for inserting at least one condenser, which is selected from the condenser group, between a power supply wiring and a ground wiring.

As further another related technology, a semiconductor integrated circuit described in document 3 (Japanese patent publication 2007-157892A) is cited. In document 3, it is described that a capacitor is provided between a power supply and a ground as a decoupling capacitor.

### SUMMARY

In order to control the capacitance, control lines are connected to the variable capacitor cells. When deciding a layout of the semiconductor integrated circuit, an arrangement of the logic cells is firstly decided in a predetermined region (a layout region). After that, the variable capacitor cells are arranged in a free space of the layout region. A location of the free space is depended on a location of the logic cells. Accordingly, the variable capacitor cells are arranged in a random place. The control lines are required to be connected to the randomly arranged variable capacitor cells.

It is considered that the control lines are arranged all over the layout region in order to easily connecting the variable capacitor cells and the control lines.

FIG. 1 is a diagram showing an example of a layout of the semiconductor integrated circuit 100. The semiconductor integrated circuit 100 shown in FIG. 1 includes a surrounding region 102, a logic cell region 103, and a plurality of variable capacitor cell 101. In FIG. 1, a X direction and a Y direction are defined. In the logic cell region 103, numerous logic cells (not illustrated) are arranged. The surrounding region 102 is arranged so as to surround the logic cell region 103. In the surrounding region 102, an IO baffler, a rounding line of a power supply VDD, a rounding line of a ground GND, and a rounding line of a control line (Vcb line) are arranged. In a part of FIG. 1, power supply lines (VDD lines), ground lines (GND line), and control lines (Vcb lines) are illustrated. The power supply lines and the ground lines are evenly arranged so as to be connected to all of the logic cells included in the logic cell region 103. Specifically, the power supply lines include: numerous Y direction VDD lines extending in the Y direction; and numerous X direction VDD lines extending in the X direction. The ground lines include: numerous Y direction GND lines extending in the Y direction; and numerous X direction GND lines extending in the X direction. Namely, the power supply lines and the ground lines are arranged to have a meshed shape, respectively. Since the power supply lines and the ground lines are evenly arranged, all of the logic cells and variable capacitor cells 101 are easy to be connected to the nearest power supply line and the nearest ground line. Here, the control lines Vcb are also evenly arranged, as the power supply lines and the ground lines. Namely, the control lines Vcb include numerous X direction Vcb lines (control line elements) extending in the X direction. Accordingly, the each variable capacitor cell 101 is easily connected to the nearest control line Vcb, regardless of the position.

However, if the control lines Vcb are evenly arranged as shown in FIG. 1, a space for arranging the logic cells is limited. As a result, it becomes difficult to carry out the automatic placement and rooting, when arranging the logic cells. Moreover, an amount of the logic elements that is able to be installed is limited. Accordingly, there is a problem in a cost of the semiconductor integrated circuit.

The layout method for the semiconductor integrated according to the present invention includes: generating logic cell layout data by deciding layouts of logic cells and signal lines connected to the logic cells with using an automatic place and rout tool; generating variable capacitor cell layout data by deciding layouts of variable capacitor cells and control lines for controlling the capacitance of the variable capacitor cells with using the automatic place and rout tool; and generating layout data of the semiconductor integrated circuit based on the logic cell layout data and the variable capacitor cell layout data. The generating the variable capacitor cell data includes, arranging the control lines so as to be same as the signal lines in a resistance of a unit length in one wiring layer.

According to this invention, the control lines are arranged with using the automatic place and rout tool. Accordingly, the control lines are arranged in only a necessary position, without being evenly arranged. As the results, a space for arranging the control lines can be suppressed to be a requisite minimum, and a space for the logic cells can be sufficiently reserved.

The layout device for the semiconductor integrated circuit according to the present invention includes: a logic cell layout section configured to generate logic cell layout data by deciding layouts of logic cells and signal lines connected to the logic cells, with using an automatic place and root tool; a variable capacitor cell layout section configured to generate variable capacitor cell data by deciding layouts of variable capacitor cells and control lines for controlling capacitance of the variable capacitor cells, with using the automatic place and root tool; and a layout data generating section configured to generate layout data of the semiconductor integrated circuit, based on the logic cell layout data and the variable capacitor cell layout data. The variable capacitor cell layout section arranges the control lines so as to be same as the signal lines in a resistance of a unit length in one wiring layers.

The semiconductor integrated circuit according to the present invention includes: a logic part including logic elements for realizing logic functions; signal lines connected to the logic part; variable capacitance elements; and control lines controlling capacitance of the variable capacitance elements. The signal lines are same as the control lines in a resistance of a unit length.

According to the present invention, a semiconductor integrated circuit, a layout method for the semiconductor integrated circuit, a layout program for the semiconductor integrated circuit, and a layout device for the semiconductor integrated circuit are provided, which can sufficiently reserve a space for arranging the logic cells.

### BRIEF DESCRIPTION OF DRAWINGS

The above and other objects, advantages and features of the present invention will be more apparent from the following description of certain preferred embodiments taken in conjunction with the accompanying drawings, in which:

FIG. 1 is diagram showing one example of a layout of a semiconductor integrated circuit;

FIG. 2 is a diagram showing a layout of a semiconductor integrated circuit according to a first embodiment;

FIG. 3 is a diagram schematically showing a variable capacitor cell in the first embodiment;

FIG. 4 is a block diagram showing a layout device for the semiconductor integrated circuit according to the first embodiment;

FIG. 5 is a flow chart showing a layout method for the semiconductor integrated circuit according to the first embodiment;

FIG. 6 is a layout diagram showing a layout method of the semiconductor integrated circuit according to a second embodiment;

FIG. 7 is a flow chart showing a layout method for the semiconductor integrated circuit according to the second embodiment;

FIG. 8 is diagram for explaining an operation at step S52; and

FIG. 9 is a diagram showing a variable capacitor cell in a third embodiment.

### DESCRIPTION OF THE PREFERRED EMBODIMENTS

### First Embodiment

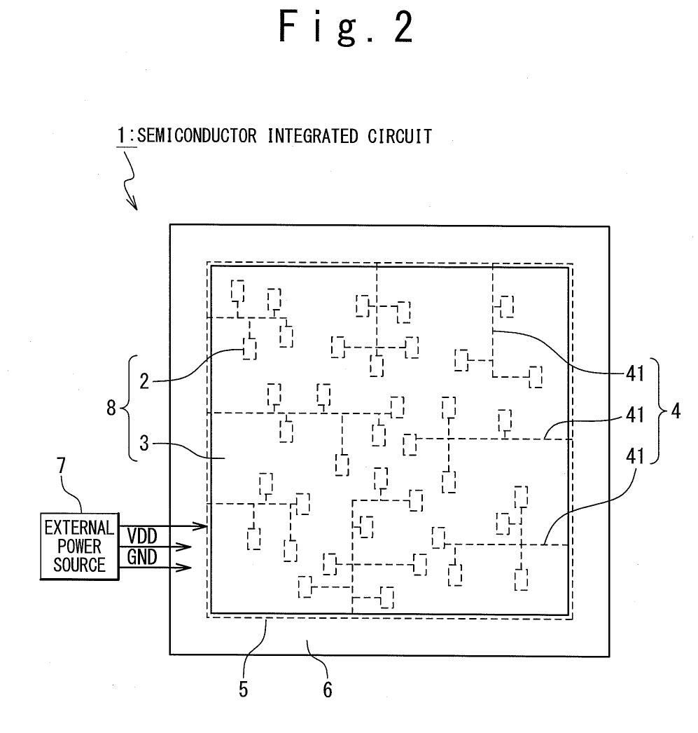

FIG. 2 is a diagram showing a layout of a semiconductor integrated circuit 1 according to the present embodiment. The semiconductor integrated circuit 1 includes at least one wiring layers. If the semiconductor integrated circuit is an ACIC, the number of the wiring layers is 5 to 6. In FIG. 2, a layout of one wiring layer is illustrated. As shown in FIG. 2, the semiconductor integrated circuit 1 includes a center region 8 and a surrounding region 6.

In the center region 8, numeral logic cells are arranged to form logic cell region 3. Also, in the center region 8, a plurality of variably capacitor cell 2 are arranged in a position (a free region) in which the logic cells are not arranged.

The surrounding region 6 is arranged to surround the center region 8. Though there is not illustrated, in the surrounding region 6, IO buffers, a power supply rounding line and a ground rounding line are provided.

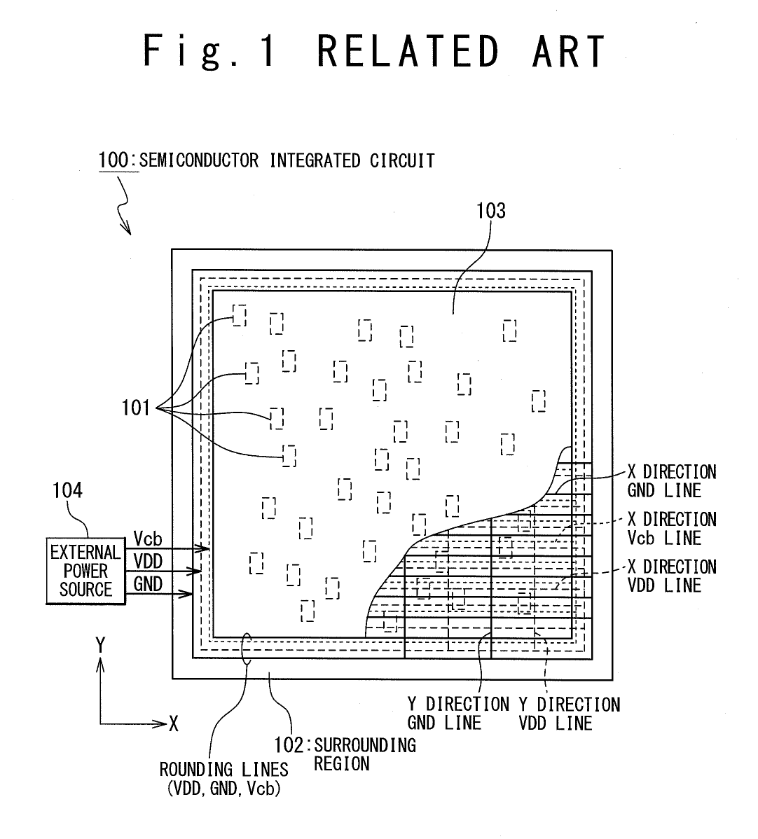

Similar to the example shown in FIG. 1, in the center region 8, power supply lines and ground lines are respectively arranged to have a meshed shape (not shown in FIG. 2). The each logic cell arranged in the logic cell region 3 is connected to the nearest power supply line and the nearest ground line. Additionally, the power supply lines and the ground lines are connected to the power supply rounding line and the ground rounding line at the surrounding region 6, respectively. The power supply rounding line and the ground rounding line are connected to an external power source 7. A power supply voltage is supplied to the each logic cell from the external power source 7, via the power supply rounding line and the power supply lines. A ground voltage is supplied to the each logic cell from the external power source 7, via the ground rounding line and the ground lines.

In the center region 8, signal lines are provided to be connected to the logic cells, though these are not shown in the drawings. The each power supply line is set to be wide so as to stably supply a voltage and a current. On the other hand, a width of the each signal line is set to be narrow in order to increase a number of the signal lines to input and output many signals.

As a result, a resistance of the each signal line in a unit length is larger than that of the each power supply line. For example, the resistance of the each signal line in a unit length is 10 to 100 (mΩ/mm), and that of the each power supply line is 100 to 1000 (mΩ/mm). Moreover, the signal lines are arranged by using an automatic place and root tool (details will be described later). The automatic place and root tool arranges the plurality of signal line to have a predetermined interval. Accordingly, the signal lines are arranged to have a predetermined pitch, without having the meshed shape.

In the center region 8, control lines 4 are further provided. The control lines 4 are connected to the variable capacitor cells 2. The control lines 4 supply control voltage to the variable capacitor cells 2 in order to control capacitance of the variable capacitor cells 2. Here, in the surrounding region 6, a Vcb rounding line 5 is arranged, and the control lines 4 are connected to the Vcb rounding line 5. The Vcb rounding line 5 is connected to the external power source 7. Namely, the control voltage is supplied to the variable capacitor cells 2, via the external power source 7, the Vcb rounding line 5 and the control lines 4.

Here, the control lines 4 are not evenly arranged. The control lines 4 include a plurality of control line elements 41. Each of the plurality of the control line elements 41 is connected to at least one variable capacitor cells 2. The each control line element 41 is arranged at only a necessary position for connection with the variable capacitor cells. Also, the each control line element 41 is same as the each signal line in a configuration. Namely, a resistance of the each control line 4 in a unit length is same as that of the each signal line, and is larger than that of the each power supply line. A width of the each control line 4 (a width of the control line element 41) is same as that of the each signal line, and is narrower than that of the each power supply line. Furthermore, a wiring pitch of the control lines 4 (an interval between adjacent control line elements 41) is same as that of the signal lines.

As mentioned above, since the control lines 4 are arranged at only a necessary position, a space for the logic cells and the signal lines can be sufficiently reserved. Subsequently, a configuration of the each variable capacitor cell 2 will be explained.

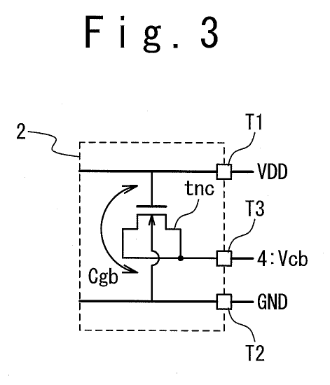

FIG. 3 is a diagram schematically showing the each variable capacitor cell 2. As shown in FIG. 3, the variable capacitor cell 2 has a capacitor element tnc formed of an N-type MOS transistor, a power supply terminal T1, a ground terminal T2 and a control terminal T3. The power supply terminal T1 is connected to the power supply lines. The ground terminal T2 is connected to the ground lines. The control terminal T3 is connected to the control lines 4. A gate of the capacitor element tnc is connected to the power supply terminal T1. A back gate of the capacitor element tnc is connected to the ground terminal T2. A source and a drain of the capacitor element are connected to the control terminal T3.

Here, a capacitance value Cgb will be focused, which is formed between a power supply VDD and a ground GND in the each variable capacitor cell 2. The capacitance value Cgb is a maximum value when the ground voltage is supplied as the control voltage. The capacitance value Cgb is a minimum value when the power supply voltage is supplied as the control voltage. Accordingly, the capacitance formed in the each variable capacitor cell 2 can be controlled by a level of the control voltage. The control voltage is variable between the power supply voltage VDD and the ground voltage GND.

Subsequently, a layout device and an operation method for designing the semiconductor integrated circuit having the configuration mentioned above will be explained.

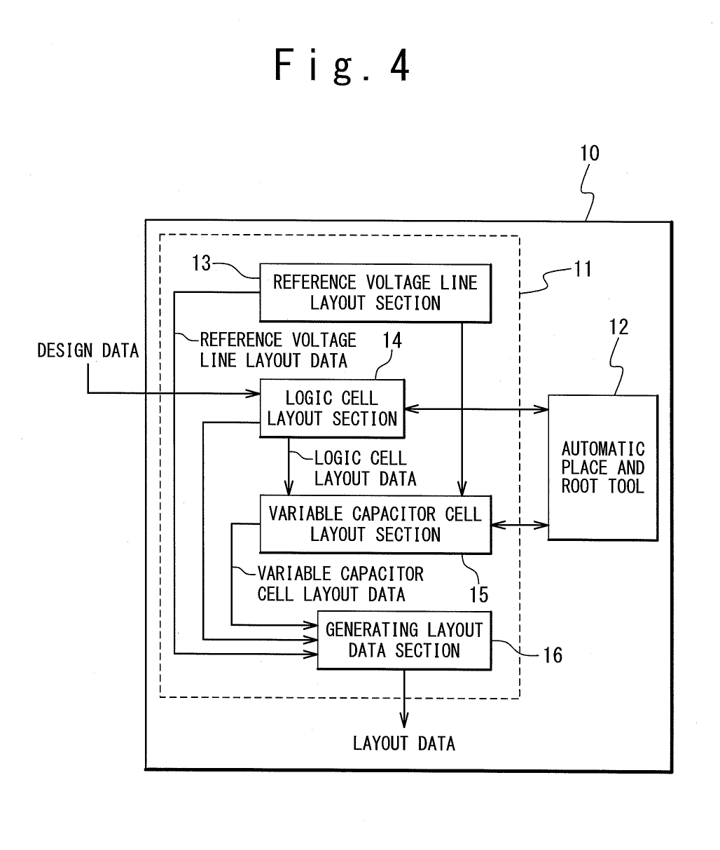

FIG. 4 is a block diagram showing a layout device 10 for the semiconductor integrated circuit according to the present embodiment. The layout device 10 includes a reference voltage line layout section 13, a logic cell layout section 14, a variable capacitor cell layout section 15, a generating layout data section 16, and an automatic place and root tool 12. Among them, the reference voltage line layout section 13, the logic cell layout section 14, the variable capacitor cell layout section 15, and the generating layout data section 16 are realized by a layout program 11 for the semiconductor integrated circuit. The layout program 11 and the automatic place and root tool 12 are installed in a computer by a recording medium.

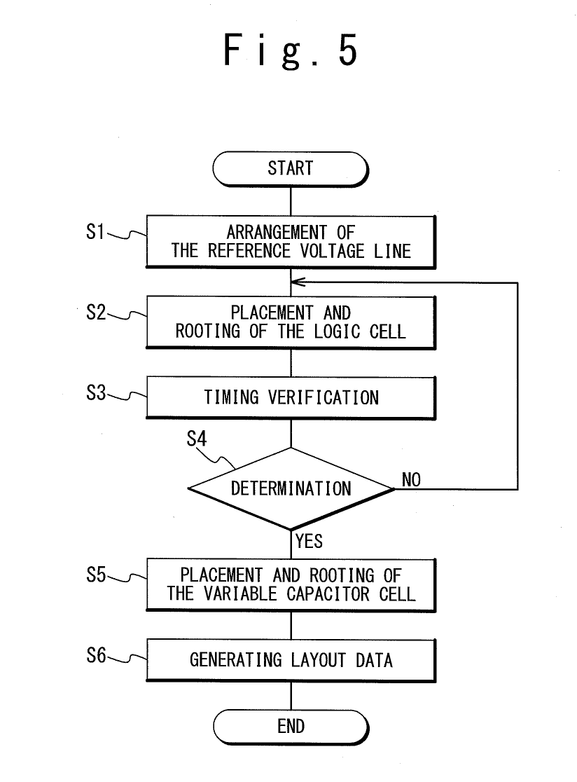

FIG. 5 is a flow chart showing a layout method for the semiconductor integrated circuit according to the present invention.

STEP S1; layout of the reference voltage lines

Firstly, the reference voltage line layout section 13 set the center region 8 as a layout region. Then the power supply lines and the ground lines are arranged in the center region 8. The power supply lines and the ground lines are arranged to have a meshed shape. The reference voltage layout section 13 generates reference voltage line layout data that indicates positions of the power supply lines and the ground lines.

STEP S2; Placement and rooting of the logic cells

Furthermore, the logic cell layout section 14 obtains a design data (data indicating connection relationships of logic elements or the like) that is preliminary prepared. Then, the logic cell layout section 14 arranges a plurality of the logic cell in the center region 8 by using the automatic place and root tool 12. Further, the signal lines for inputting and outputting signals between the plurality of logic cell are arranged, by using the automatic place and root tool 12. The logic cell layout section 14 generates logic cell layout data that indicates layouts of the plurality of the logic cell and the signal lines.

STEP S3,4; Timing verification and determination

Next, the logic cell layout section 14 carries out timing verification, based on the logic cell layout data (STEP S3). If a result of the timing verification is desirable, an operation of next STEP S5 is carried out. On the other hand, the result is not desirable, the operation of STEP S2 is carried out again, and the placement and rooting of the logic cells is carried out again.

STEP S5; Placement and rooting of the variable capacitor cells

Subsequently, the variable capacitor cell layout section 15 arranges a plurality of the variable capacitor cell 2 in a free space of the center region 8. Further, the variable capacitor cell layout section 15 arranges control lines 4 connected to the variable capacitor cells 2. As a result, the variable capacitor cell layout data is generated.

Here, the variable capacitor cell layout section 15 arranges the variable capacitor cells 2 and the control lines 4 by using the automatic place and root tool 12, similar to the operation of STEP S2. As a result, the control lines 4 are arranged in only a necessary position, without being arranged all over the center region 8. Furthermore, the control lines 4 has a configuration same as the signal lines that connects the plurality of logic cells. Namely, a resistance value of the each control line 4 in a unit length is same as that of the each signal line in one wiring layer, and is larger than that of the each power supply line. Further, a width of the each control line 4 is same as that of the each signal line in one wiring layer, and is lower than that of the each power supply line. Furthermore, a wiring pitch of the control lines 4 (an interval between adjacent control lines 4) is same as that of the signal lines in one wiring layer.

STEP S6; Generating layout data

Next, the layout data generating section 16 generates layout data indicating a whole layout of the semiconductor integrated circuit, based on the reference voltage line layout data, the logic cell layout data and the variable capacitor cell layout data. The layout data is outputted as a layout result.

By the operations in STEP S1 to S6, the semiconductor integrated circuit according to the present embodiment is designed.

As described above, according to the present embodiment, the variable capacitor cells 2 and the control lines 4 are arranged by using the automatic place and root tool 12. Accordingly, the control lines 4 are arranged in only a necessary position. As a result, a space for the logic cell region 3 is not limited by the control lines 4, and the logic cells can be arranged in high density.

In the present embodiment, the control voltages are supplied to the variable capacitor cells 2 by the control line elements 41 that are narrower than the power supply lines in a wiring width. Namely, the control voltages are supplied by control lines 4 whose resistance is higher than that of the power supply lines. When one control line 4 is connected to a plurality of the variable capacitor cell 2, a current leaking to the each variable capacitor cell 2 may be occurred. As a result, a voltage drop is occurred in the control lines 4, and a controllable voltage range may be narrow.

Therefore, the voltage drop in the each control line 4 will be estimated by using parameters of an ASIC of 150 nm class that is generally used. Generally, the resistance value of the each power supply line is 10 to 100 mΩ/mm. On the other hand, the resistance value of the each signal line (control lines 4) is larger than 100 mΩ/mm. Moreover, a leaking current flowing to the each variable capacitor cell 2 from the each control line 4 is several nA/unit to several ten nA/unit. A whole leaking current in all of the control lines 4 can be controlled, by limiting a number of the variable capacitor cells 2 connected to one control line element 41. For example, if a rule of a fun-out function of the automatic place and root tool 12 is applied, a whole amount of the leaking current is easily controlled to be less than 1000 nA. Also, a length of one control line element 41 is easily controlled by the automatic place and root tool 12. Here, it is presumed that the resistance of one control line element 41 is 10 kΩ even in a worst case. Further, it is presumed that the whole amount of the leaking current is 1000 nA even in a worst case. Furthermore, it is presumed that all of the variable capacitor cells 2 are connected to one end of the each control line element 41. In this case, a maximum value ΔV(max) of a voltage drop (ΔV) in each control line element 41 is estimated by following equation.

ΔV(max)=1000 nA×10 kΩ=0.01V (Equation)

Here, it is presumed that a voltage difference between VDD and GND in 150 nm ASIC is 1.5V. Namely, it is presumed that a controllable range of the control voltage is 1.5V. In this case, the voltage drop value ΔV(max) in the each control line element 41 is less than 1% of the controllable range of the control voltage, and that is sufficiently small to be ignored. Namely, since the leaking current and the number of the variable capacitor cells 2 connected to one control line element 41 can be controlled by using the automatic place and root tool 12, there is no problem in operation characteristics, even if the control lines 4 and the signal lines have same configurations.

### Second Embodiment

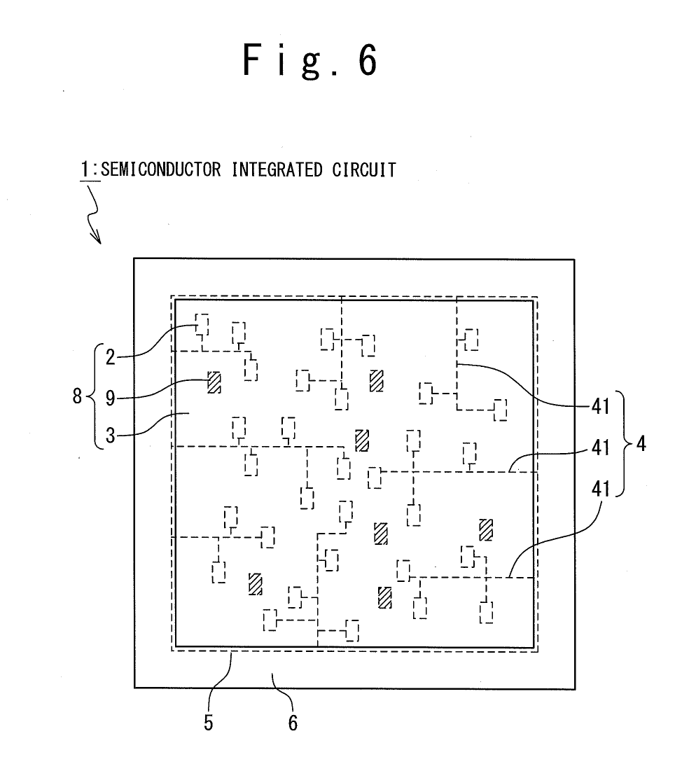

Subsequently, the second embodiment will be explained. FIG. 6 is a layout diagram showing the semiconductor integrated circuit 1 according to the present embodiment. The present embodiment defers from the first embodiment in that a fixed capacitor cell 9 is arranged in the center region 8. Other points are same as the first embodiment, and the detailed descriptions will be omitted.

In the first embodiment, at first, the logic cells and the signal lines were arranged. After that, the variable capacitor cells 2 and the control lines 4 were arranged. If the logic cells 2 and the signal lines are densely arranged, there is a case that the control lines 4 cannot be arranged to be connected some of the variable capacitor cells 2. In such cases, it is considered to carry out the placement and rooting of the logic cells again. However, if the placement and rooting of the logic cells is carried out again, a period for designing is increased. Furthermore, it may be difficult to arrange the logic cells so as to obtain desired characteristics.

The plurality of the variable capacitor cell 2 are provided for enabling a resonance band to be changed after manufacturing. Accordingly, respective capacitor cells is not required to be a variable capacitor cell, if entire capacitance value is variable. Even though depending on the resonance band to be changed, if 50% of the plurality of capacitor cell are the variable capacitor cells, it is acceptable.

For this reason, in the present embodiment, as shown in FIG. 6, a part of the plurality of variable capacitor cells is replaced by fixed capacitor cells 9. The fixed capacitor cells 9 are not connected to the control lines 4.

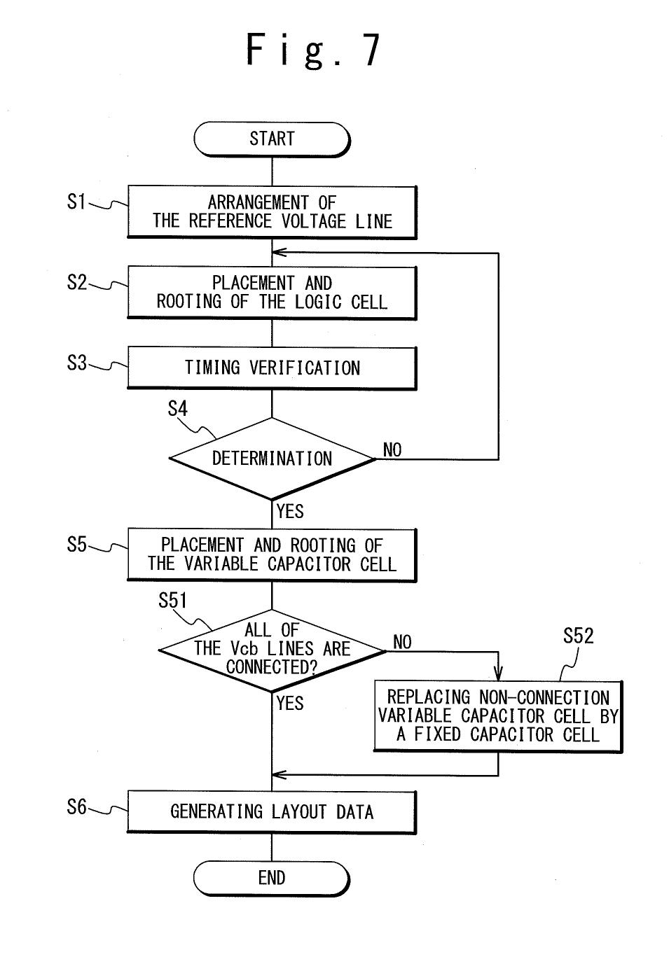

FIG. 7 is a flow chart showing a layout method for the semiconductor integrated circuit according to the present invention. Operations from STEP S1 to S5 are same as those of the first embodiment. Accordingly, detailed descriptions will be omitted.

In the present embodiment, the variable capacitor cell layout section 15 determines whether or not the control lines 4 are connected to all variable capacitor cells 2 (STEP S51). If the control lines 4 are connected to all variable capacitor cells 2, the operation of STEP S6 is executed to generate the layout data.

On the other hand, if a variable capacitor cell 2 (a non-connection variable capacitor cell) that is not connected to the control lines 4 exists, the variable capacitor cell layout section 15 replaces the non-connection variable capacitor cell by the fixed capacitor cell 9 (STEP S52).

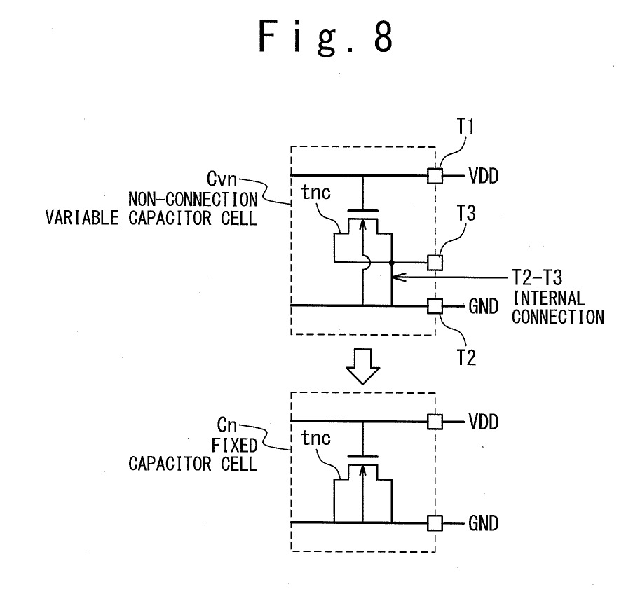

FIG. 8 is a diagram showing an operation of STEP S52. As shown in FIG. 8, the variable capacitor cell layout section 15 connects the control terminal T3 and the ground terminal T2 in the non-connection variable cell. By this, the non-connection variable capacitor cell is replaced by the fixed capacitor cell 9. In the fixed capacitor cell 9, the ground voltage GND is supplied as the control voltage Vcb. As a result, the capacitance value Cgb of the fixed capacitor cell 9 is fixed to be a maximum value.

### Third Embodiment

Next, the third embodiment will be explained. In the present embodiment, configurations of the variable capacitor cells 2 are changed from those of the embodiments mentioned above. Moreover, the control lines 4 include a first control line element 4-1 and a second control line element 4-2. The first control line element 4-1 and the second control line element 4-2 supply different voltages to the variable capacitor cells 2. Other points are same as those of the embodiments mentioned above, and detailed descriptions will be omitted.

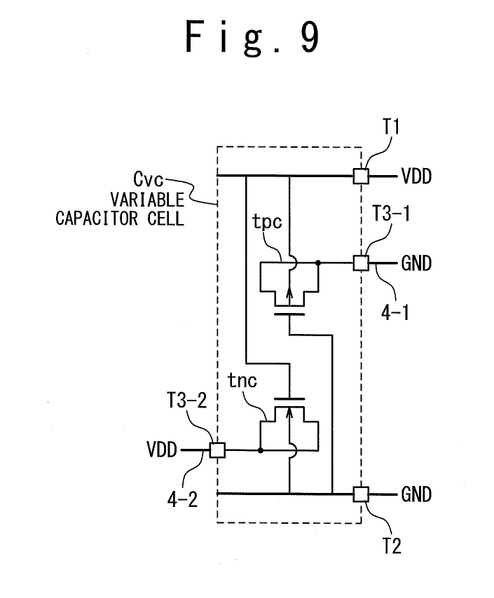

FIG. 9 is a diagram showing the each variable capacitor cell 2 in the present embodiment. In the embodiments mentioned above, the case was explained in which the transistor included in the each variable capacitor cell 2 was N type transistor. On the other hand, in the present embodiment, in the each variable capacitor cell 2, an N-type transistor tnc and a P-type transistor tpc are included. A gate of the P-type transistor tpc is connected to the ground terminal T2. A back gate of the P-type transistor tpc is connected to the power supply terminal T1. A drain and a source of the P-type transistor tpc are connected to the first control terminal T3-1. The first control terminal T3-1 is connected to the first control line element 4-1. A gate of the N-type transistor tnc is connected to the power supply terminal T1. A back gate of the N-type transistor tnc is connected to the ground terminal T2. A source and a drain of the N-type transistor tnc are connected to the second control terminal T3-2. The second control terminal T3-2 is connected to the second control line element 4-2.

In the present embodiment, a capacitance value of the N-type transistor tnc is a maximum value when a voltage (a first control voltage) supplied from the first control line element 4-1 is the ground voltage. Further, this capacitance value is a minimum value when the first control voltage is the power supply voltage. On the other hand, a capacitance value of the P-type transistor tpc is a maximum value when a voltage (a second control voltage) supplied from the second control line element 4-2 is the power supply voltage, and is a minimum value when the second control voltage is the ground voltage. Namely, tendencies in a change of the capacitance value by the control voltage are opposite to each other between the N-type transistor and the P-type transistor.

According to the present embodiment, since two transistors are included in one variable capacitor cell, the capacitance value of the each variable capacitor cell 2 can be increased.

As mentioned above, the present invention has been described by illustrating the first to third embodiments. However, these embodiments are not independent each other, and it is possible to employ a combination of them if there is no confliction.

Although the inventions has been described above in connection with several preferred embodiments thereof, it will be apparent to those skilled in the art that those embodiments are provided solely for illustrating the invention, and should not be relied upon to construe the appended claims in a limiting sense.

What is claimed is:

1. A layout method for a semiconductor integrated circuit, comprising:
generating logic cell layout data by arranging logic cells and signal lines connected to said logic cells, by using an automatic place and root tool;
generating variable capacitor cell layout data by arranging variable capacitor cells and control lines for controlling capacitance value of said variable capacitor cells, by using said automatic place and root tool; and
generating layout data of said semiconductor integrated circuit, based on said logic cell layout data and said variable capacitor cell layout data,
wherein said generating variable capacitor cell layout data comprises, arranging said control lines so as to be same as said signal lines in a resistance of a unit length in one wiring layer.

2. The layout method for the semiconductor integrated circuit according to claim 1, wherein said generating variable capacitor cell layout data comprises, arranging said control lines so as to be same as said signal lines in a line width.

3. The layout method for the semiconductor integrated circuit according to claim 1, wherein said generating variable capacitor cell layout data comprises, arranging said control lines so as to be same as said signal lines in a line pitch.

4. The layout method for the semiconductor integrated circuit according to claim 1, further comprising:
generating reference voltage line data by arranging power supply lines for supplying a power supply voltage to said logic cells and arranging ground lines for supplying a ground voltage to said logic cells,
wherein said generating layout data comprises, generating said layout data based on said reference voltage line data.

5. The layout method for the semiconductor integrated circuit according to claim 4, wherein said generating reference voltage line data comprises, arranging said power supply lines and said ground lines such that said power supply lines and said ground lines have a meshed shape, respectively.

6. The layout method for the semiconductor integrated circuit according to claim 4, wherein said generating variable capacitor cell layout data comprises, arranging transistors as said variable capacitor cells, and each of said transistors comprises a gate, a back gate connected to a ground terminal, a source region, and a drain region,
wherein said gate is connected to one of said power supply lines and said ground lines,
wherein said back gate is connected to the other of said power supply lines and said ground lines, and
wherein said source region and said drain region are connected to said control lines.

7. The layout method for the semiconductor integrated circuit according to claim 4, wherein said generating variable capacitor cell comprises:
arranging a P-channel type transistor and a N-channel type transistor as each of said variable capacitor cells; and
arranging a first control line and a second control line as said control lines,
wherein a gate of said P-channel type transistor and a back gate of said N-channel type transistor are connected to said ground lines,
wherein a gate of said N-channel type transistor and a back gate of said P-channel type transistor are connected to said power supply lines,
wherein a source and a drain of said P-channel type transistor are connected to said first control line, and
wherein a source and a drain of said N-channel type transistor are connected to said second control line.

8. The layout method for the semiconductor integrated circuit according to claim 1, wherein said generating variable capacitor cell layout data comprises:
arranging said variable capacitor cells;
arranging said control lines so as to be connected to said variable capacitor cells;
determining whether or not all of said variable capacitor cells are connected to said control lines; and
replacing a variable capacitor cell not connected to said control lines by a fixed capacitor cell if said variable capacitor cell not connected to said control lines exists.

9. A computer-readable recording medium in which a computer-readable program is recorded to realize a layout method for the semiconductor integrated circuit, wherein said method comprises:
generating logic cell layout data by arranging logic cells and signal lines connected to said logic cells, by using an automatic place and root tool;
generating variable capacitor cell layout data by arranging variable capacitor cells and control lines for controlling capacitance value of said variable capacitor cells, by using said automatic place and root tool; and
generating layout data of said semiconductor integrated circuit, based on said logic cell layout data and said variable capacitor cell layout data,
wherein said generating variable capacitor cell layout data comprises, arranging said control lines so as to be same as said signal lines in a resistance of a unit length in one wiring layer.

10. A layout device for a semiconductor integrated circuit, comprising:
a logic cell layout section configured to generate logic cell layout data by arranging logic cells and signal lines connected to said logic cells, by using an automatic place and root tool;
a variable capacitor cell layout section configured to generate variable capacitor cell layout data by arranging variable capacitor cells and control lines for controlling capacitance of said variable capacitor cells, by using said automatic place and root tool; and
a layout data generating section configured to generate layout data of the semiconductor integrated circuit, based on said logic cell layout data and said variable capacitor cell layout data,
wherein said variable capacitor cell layout section is configured to arrange said control lines so as to be same as said signal lines in a resistance of a unit length in one wiring layer.

11. A semiconductor integrated circuit, comprising
a logic part including logic elements for realizing logic functions;
signal lines connected to said logic part;
variable capacitor cells; and
control lines configured to control capacitance of said variable capacitor cells,
wherein said signal lines are same as said control lines in a resistance of a unit length in one wiring layer.
